(19) United States
(12) Patent Application Publication
(10) Pub. No.: US 2014/0373782 A1
(43) Pub. Date: Dec. 25, 2014

(54) SUBSTRATE SUPPORT APPARATUS AND SUBSTRATE PROCESS APPARATUS HAVING THE SAME

(71) Applicant: WONIK IPS CO., LTD., Pyeongtaek-Si (KR)

(72) Inventors: Yong Gyun PARK, Anseong-Si (KR); Tae Wook SEO, Suwon-Si (KR); Nae Il LEE, Osan-Si (KR)

(21) Appl. No.: 14/311,207

(22) Filed: Jun. 20, 2014

(30) Foreign Application Priority Data
Jun. 21, 2013 (KR) 10-2013-0071452

(51) Int. Cl. H01J 37/32

(52) U.S. Cl. CPC H01J 37/32137; H01J 37/32532; H01J 37/32715
USPC 118/723 R; 118/500

(57) ABSTRACT

Provided is a substrate processing apparatus. The substrate processing apparatus includes a chamber in which a processing space is defined, a substrate support disposed in the chamber and supporting a substrate; and an upper electrode to which a radio frequency (RF) power is applied, the upper electrode facing the substrate support. The substrate support includes a plurality of ground electrodes spaced apart from each other and independently controlled so that plasma is uniformly generated to an edge area of the substrate support between the upper electrode and the substrate support. The substrate processing apparatus may uniformly control plasma distribution or density on a substrate and a periphery of the substrate and may uniformly control plasma distribution or density in the central area of the substrate and the edge area of the substrate.

### CROSS-REFERENCE TO RELATED APPLICATION

This application claims priority to Korean Patent Application No. 10-2013-0071452 filed on Jun. 21, 2013 and all the benefits accruing therefrom under 35 U.S.C. §119, the contents of which are incorporated by reference in their entirety.

### BACKGROUND

The present disclosure relates to a substrate support device and a substrate processing apparatus having the same, and more particularly, to a substrate support device capable of controlling plasma distribution and a substrate processing apparatus having the same.

Various electronic devices such as semiconductor memories are manufactured through lamination of various thin films. That is, various thin films are formed on a substrate, and then the thin films are patterned through a photolithographic process to form a device structure.

There are various thin films in accordance with materials forming the thin films, for example, conductive films, dielectric films, insulative films, and the like, and also there are various methods of manufacturing the thin films. The methods of manufacturing the thin films are mainly classified into physical methods and chemical methods. Recently, plasma is being used during a manufacturing process so as to efficiently manufacture the thin film. When the thin film is formed on the substrate using plasma, a thin film forming temperature may decrease, and a thin film depositing speed may increase.

However, when plasma is used to manufacture the thin film, it is difficult to control the plasma as desired within the chamber in which the process for manufacturing the thin film is performed.

For example, when a thin film is manufactured in the process chamber having a substrate support supporting a substrate and an upper electrode facing the substrate support, a high-frequency power, e.g., a radio frequency (RF) power is applied to the upper electrode, and a ground electrode disposed in the substrate support is grounded. Then, plasma is generated between the upper electrode and the substrate support to form a thin film on the substrate. However, there is a limitation in that the plasma generated between the upper electrode and the substrate support is differently distributed in a central area of the substrate support and an edge area of the substrate support and the plasma has a different state in each of the central area and the edge area of the substrate support. When there is a difference in plasma distribution or state between the central area and edge area of the substrate support, it is difficult to manufacture the thin film having a uniform thickness on the substrate.

Therefore, technologies for adjusting a structure of gas spray unit, a method of spraying gas, and so on are being suggested, however, those technologies require excessive cost and time.

### SUMMARY

The present disclosure provides a substrate support device and a substrate processing apparatus, which are capable of uniformly controlling plasma distribution on a substrate and a periphery of the substrate.

The present disclosure also provides a substrate support device and a substrate processing apparatus which are capable of forming a thin film on a substrate to a uniform thickness.

In accordance with an exemplary embodiment, a substrate support device supporting a substrate includes: a substrate support on which the substrate is seated, the substrate support having a protrusion protruding from an edge area thereof; a first ground electrode disposed in a central area of the substrate support; a second ground electrode spaced apart from the first ground electrode and disposed in the edge area of the substrate support; and a control unit independently controlling the first and second ground electrodes.

The substrate support may include an insulation material and a heater disposed below at least one of the first ground electrode and the second ground electrode.

The first ground electrode may have a size less than that of the substrate, and the second ground electrode may have an inner diameter greater than that of the substrate. The first ground electrode may have a first wave-shaped part on an outer circumferential surface thereof, and the second ground electrode may have a second wave-shaped part on an inner circumferential surface, the second wave-shaped part corresponding to the first wave-shaped part. At least one portion of the first wave-shaped part may protrude outward from the substrate, and at least one portion of the second wave-shaped part may protrude inward from the substrate.

The second ground electrode may be positioned higher than the first ground electrode and disposed below the protrusion.

In accordance with another exemplary embodiment, a substrate processing apparatus includes: a chamber in which a processing space is defined; a substrate support disposed in the chamber and supporting a substrate; and an upper electrode to which a radio frequency (RF) power is applied, the upper electrode facing the substrate support, wherein the substrate support includes a plurality of ground electrodes spaced apart from each other and independently controlled so that plasma is uniformly generated to an edge area of the substrate support between the upper electrode and the substrate support.

The plurality of ground electrodes may include a first ground electrode having a shape corresponding to that of the substrate and a second ground electrode disposed outside the first ground electrode. The first ground electrode may have a size less than that of the substrate, and the second ground electrode may be disposed outside the substrate.

The plurality of ground electrodes may include the first ground electrode having a first curve on an outer circumferential surface thereof and the second ground electrode having a second wave-shaped part on an inner circumferential surface thereof, wherein at least one portion of the first wave-shaped part protrudes outward from the substrate, and the second wave-shaped part is disposed outside the first ground electrode and corresponds to the first wave-shaped part.

The substrate processing apparatus may include a control unit respectively controlling impedances of the plurality of ground electrodes. The control unit may include at least one of a variable condenser, a variable coil, and a variable resistor and may allow the plurality of ground electrodes to have different impedances.

The substrate support may include an insulator, and the ground electrode is formed in a film shape in the insulator.

### BRIEF DESCRIPTION OF THE DRAWINGS

Exemplary embodiments can be understood in more detail from the following description taken in conjunction with the accompanying drawings, in which:

FIG. 1 is a schematic cross-sectional view of a substrate processing apparatus in accordance with an exemplary embodiment;

FIG. 2 is a schematic cross-sectional view of a substrate support device in accordance with an exemplary embodiment;

FIG. 3 is a plan view of the substrate support device in accordance with an exemplary embodiment;

FIG. 4 is a plan view of a substrate support device in accordance with a modified example; and

FIG. 5 is a conceptual view illustrating a state where a plasma is generated in the substrate processing apparatus in accordance with an exemplary embodiment.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout

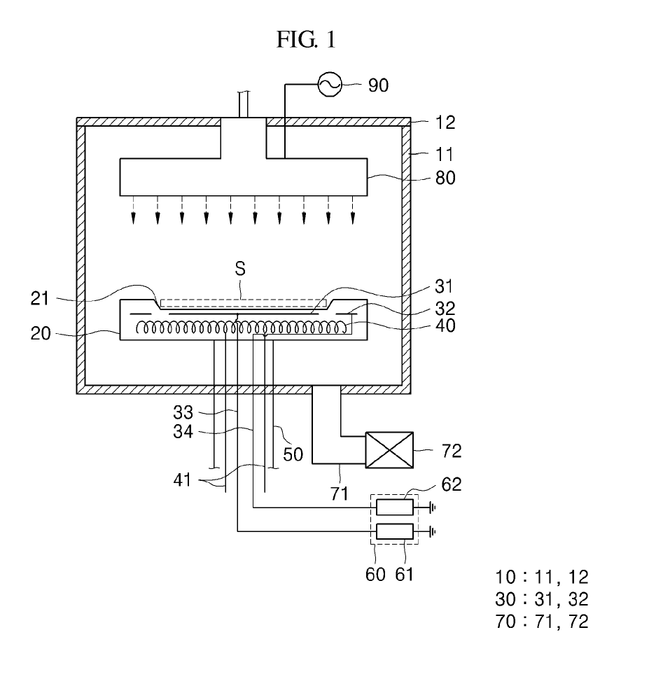

FIG. 1 is a schematic cross-sectional view of a substrate processing apparatus in accordance with an exemplary embodiment.

Referring to FIG. 1, a substrate processing apparatus according to an exemplary embodiment includes a chamber in which a processing space is defined; a substrate support disposed in the chamber and supporting a substrate; and an upper electrode to which a radio frequency (RF) power is applied, the upper electrode facing the substrate support, wherein the substrate support includes a plurality of ground electrodes spaced apart from each other and independently controlled so that plasma is uniformly generated to an edge area of the substrate support between the upper electrode and the substrate support. Also, the substrate processing apparatus includes a rotation shaft for supporting and moving the substrate support 20 and a vacuum formation part 70 forming a vacuum atmosphere in the chamber. Also, the upper electrode 80 may function as a gas spray unit supplying gas into the chamber 10.

The substrate processing apparatus is an apparatus in which various processing processes are performed on the substrate S after the substrate S is loaded into the chamber 10. For example, a wafer is loaded into the chamber 10 to manufacture a semiconductor device, and then process gas is supplied onto the wafer through the gas spray unit to form a thin film on the wafer.

The chamber 10 (11 and 12) includes a body 11 of which an upper portion is opened and a top lid 12 openably disposed on the upper portion of the body 11. When the top lid 12 is coupled to the upper portion of the body 11 to close down the body 11, a space where the processing process, for example, a deposition process with respect to the substrate S is performed is defined in the chamber 10. Since the vacuum atmosphere is formed in the space in general, an exhaust tube 71 for exhausting the gas existing in the space is connected to a predetermined position of the chamber 10, for example, bottom or side surfaces of the chamber 10, and the exhaust tube 71 is connected to a vacuum pump 72. Also, a through hole to which the rotation shaft 50 of the substrate support 30 that will be described later is defined in the bottom surface of the body 11. A gate valve (not shown) for loading the substrate S into the chamber 10 or unloading the substrate S to the outside is disposed on a side wall of the body 11.

The substrate support 20 is an element for supporting the substrate S and disposed at a lower side of the inside of the chamber 10. Also, the substrate support 20 may have a protrusion 21 protruding upward from an edge area thereof. The substrate support 20 is disposed on the rotation shaft 50. The substrate support 20 may have a plate shape having a predetermined thickness and have a shape similar to that of the substrate S. For example, when the substrate is a circular wafer, the substrate support 20 may be manufactured in a circular plate shape. Of course, the exemplary embodiment is not limited thereto, for example the substrate support 20 may have various shapes. The substrate support 20 is disposed in the chamber 10 in a horizontal direction. The rotation shaft 50 is vertically connected to a bottom surface of the substrate support 20. The rotation shaft 50 is connected to a driving unit (not shown) outside the chamber 10, e.g., a motor, through the through hole to allow the substrate support 20 to ascend, descend and be rotated. Here, a bellows (not shown) may be used to seal between the rotation shaft 50 and the through hole to prevent a vacuum state in the chamber 10 from being released during the substrate processing process.

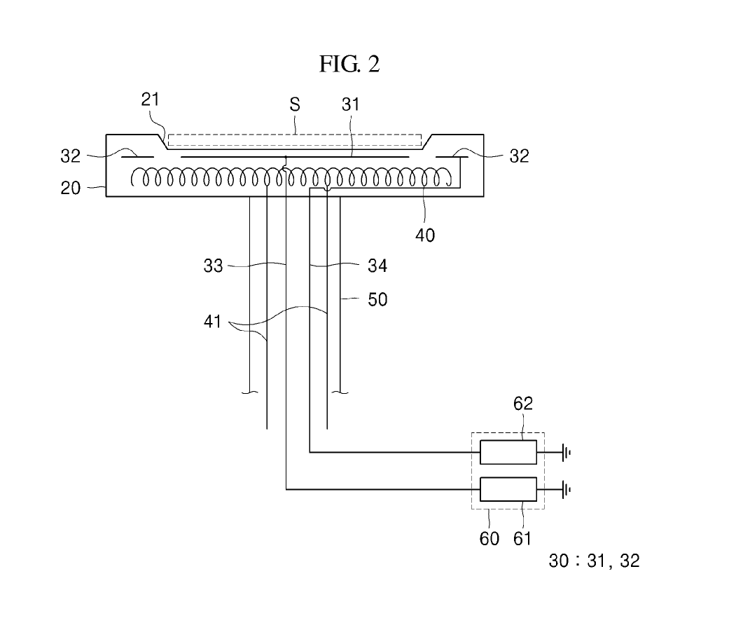

The substrate support 20 is not specially limited to a shape or a structure thereof, if the substrate support 20 has a structure for supporting the substrate. Here, a recess groove may be recessed in an area including the center of the substrate support 20 so that the substrate S is stably seated on an accurate position of the substrate support 20. That is, as illustrated in FIG. 2, the recess groove may be defined in a region of the substrate support 20 in which the center of the substrate support 20 is positioned, and has a size equal to or slightly greater than that of the substrate S, and also, the protruding protrusion 21 may be defined in the rest of the area, i.e., the edge area of the substrate support 20. Here, the protrusion 21 may have an inclined surface that is inclined toward the recess groove. Thus, the substrate S loaded into the chamber 10 may be guided into the recess groove surrounded by the protrusion 21 and then be positioned to correspond to the center of the substrate support 20, thereby being seated on the accurate position.

Also, the substrate support 20 may include an insulation material. That is, a whole substrate support 20 may be formed of an insulator, or a portion of the substrate support 20 may be formed of the insulator. Alternatively, an insulator layer may be applied onto a surface of the substrate support 20. Here, the insulator may be formed of various ceramic materials, for example, aluminum nitride (AIN), silicon carbide (SiC), and so on.

Also, a heater 40 for heating the substrate support 20 may be disposed in the substrate support 20. The heater 40 is connected to an external power source through a conductive wire. When a power is applied to the heater 40, the substrate support 20 is heated, and thus the substrate S seated on the substrate support 20 may be heated. The heater 40 is not specially limited to a method in which the heater 40 is disposed and structure thereof, and for example, the heater 40 may be disposed in various manners and structures. The heater 40 may be formed of tungsten W, molybdenum (Mo), and so on. Also, the heater 40 may be disposed below a ground electrode that will be described later. The heater 40 may be disposed below at least one of a plurality of ground electrodes. For example, the heater 40 may be disposed below at least one of a first ground electrode 31 and a second ground electrode 32. Of course, the heater 40 may be disposed in an area corresponding to the whole first ground electrode 31 and a portion of the second ground electrode 32.

Also, the plurality of ground electrodes spaced apart from each other and independently controlled are disposed in the substrate support 20. The plurality of ground electrodes will be described later.

The upper electrode 80 is spaced apart from the substrate support 20 to face the substrate support 20 in the chamber 10. The upper electrode 80 is connected to the power source 90 outside. The RF power is applied to the upper electrode 80, and the substrate support 20 is grounded, thereby exciting plasma in a reaction space that is a deposition space in the chamber 10 using the RF. Here, the substrate support is grounded through the ground electrode that will be described later. Also, the upper electrode 80 may function as the gas spray unit for supplying the gas into the chamber 10. That is, the upper electrode 80 may spray various processing gases supplied from the outside toward the substrate support 20. For example, the upper electrode 80 may spray process gas for thin film deposition. The upper electrode 80 may be disposed in the top lid 12 constituting the chamber 10 and may be connected to a plurality of gas supply sources supplying various gas different from each other. The upper electrode 80 faces the substrate support 20 and has a predetermined area similar to that of the substrate support 20. The upper electrode 80 may be manufactured in a shower-head type including a plurality of spray holes. The unit for supplying the gas into the chamber 10 may be separately manufactured from the upper electrode 80, as a nozzle or an injector type inserted into the chamber 10. The nozzle or injector type unit may be disposed to pass through the side wall of the chamber 10.

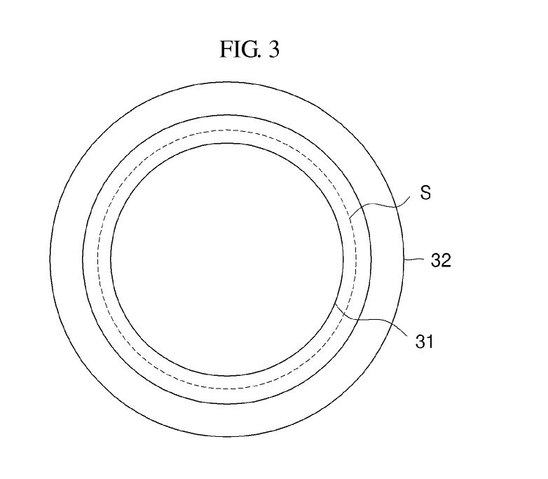

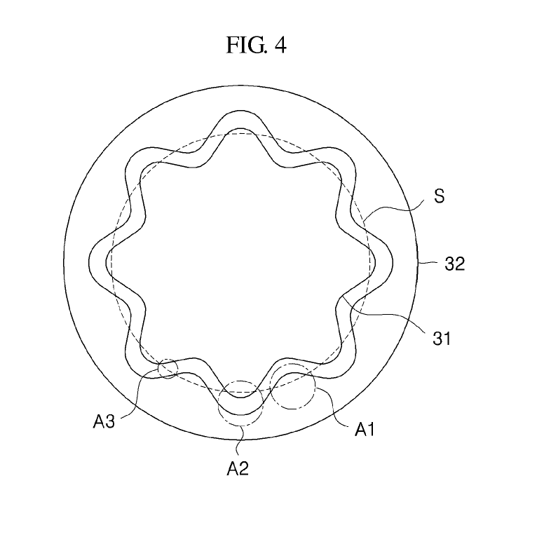

Hereinafter, the ground electrode and the substrate support device having the same will be described in detail with reference to the drawings. FIG. 2 is a schematic cross-sectional view of a substrate support device in accordance with an exemplary embodiment, FIG. 3 is a plan view of the substrate support device in accordance with an exemplary embodiment, and FIG. 4 is a plan view of a substrate support device in accordance with a modified example.

Referring to FIG. 2, the substrate support device includes the protrusion 21 protruding from the edge area of the substrate support device, the substrate support 20 on which the substrate S is seated, the first ground electrode 31 disposed in a central area of the inside of the substrate support 20, the second ground electrode 32 spaced apart from the first ground electrode 31 and disposed in an edge area of the inside of the substrate support 20, and a control unit 60 independently controlling the first and second ground electrodes 31 and 32. The substrate support device includes the plurality of ground electrodes in the substrate support 20 to generate the plasma in an area between the substrate support 20 and the above-described upper electrode 80 so that the plasma between the upper electrode 80 and the substrate support 20 is uniformly generated to the edge area of the substrate support 20.

Here, a central area of a certain object (for example, a substrate or a substrate support) represents an area including the center of the object and expanding toward the outside to have a predetermined size. Also, an edge area of a certain object represents an area including an edge of the object and expanding inward to have a predetermined size. Also, the central area and the edge area may contact each other with an interface disposed therebetween, or may be spaced apart from each other. Here, although each of the areas is not specially limited to a size thereof, for example, the central area may have a size equal to or greater than that of the edge area.

The ground electrode 30 (31 and 32) includes the first ground electrode 31 having a shape corresponding to that of the substrate S and the second ground electrode 32 disposed in an outer side of the first ground electrode 31. Also, the ground electrode 30 may be manufactured in a shape of a thin plate, a thin sheet or a film (a thin film or a thick film). Also, the ground electrode 30 may be applied in various manners. For example, the ground electrode 30 may be disposed on an inner surface of the substrate support 20 in a screen printing method. The ground electrode 30 may have a structure in which a predetermined area is filled with the ground electrode or may have a structure in which a plurality of openings are defined. Also, the ground electrode 30 may be formed of an electrically conductive material including metal, for example, tungsten (W), aluminum, molybdenum, copper, SUS, silver, gold, platinum, nickel, and the like. Of course, it is sufficient if a ground power is smoothly applied through the ground electrode, and the ground electrode is not specially limited to a shape or a structure, a material thereof.

The first ground electrode 31 has a predetermined are in a horizontal direction. The first ground electrode 31 is buried in an area including the center of the substrate support 20 and corresponding to most of an area to be occupied by the substrate S. The first ground electrode 31 may have a shape corresponding to that of the substrate S. For example, when the substrate S is a wafer having a circular plate shape, the first ground electrode 31 may have a circular plate shape. Of course, the first ground electrode 31 may have other modified shapes by using the circular plate shape as a basic structure.

The second ground electrode 32 is spaced apart from the first ground electrode 31 in the substrate support 20. Here, the first ground electrode 31 and the second ground electrode 32 are not specially limited to the distance therebetween, and for example, the first ground electrode 31 and the second ground electrode may have a distance therebetween so that each of the ground electrodes is independently controlled in electrical characteristic thereof. The second ground electrode 32 may be disposed outside the first ground electrode 31 to surround the first ground electrode 31. For example, as illustrated in FIG. 3, when the first ground electrode 31 has a circular plate shape, the second ground electrode 32 may have a ring shape surrounding the first ground electrode 31.

The first and second ground electrodes 31 and 32 may be modified in various sizes, shapes, or arrangement structures. As illustrated in FIG. 3, the first ground electrode 31 may have a size less than that of the substrate S, and the second ground electrode 32 may have an inner diameter greater than that of the substrate S. In this case, an edge area of the substrate S is disposed on a boundary area between the first and second ground electrodes 31 and 32. Also, as illustrated in FIG. 4, a first wave-shaped part may be formed on an outer circumferential surface, and a second wave-shaped part corresponding to the first wave-shaped part may be formed on an inner circumferential surface of the second ground electrode 32. Also, at least one portion of the first wave-shaped part may protrude outward the substrate S, and at least one portion of the second wave-shaped part may protrude inward the substrate S. That is, uneven wave-shaped part may be formed in the boundary area between the first and second ground electrodes 31 and 32. Here, a portion of the area of the substrate S, accurately, a portion of the edge area of the substrate S is disposed on the second ground electrode 32 (see reference symbol A1 of FIG. 4), another portion of the edge area of the substrate S is disposed on the first ground electrode 31 (see reference symbol A1 of FIG. 4), and further another portion of the edge area of the substrate S is disposed on the boundary area between the first and second ground electrodes 31 and 32. When the wave-shaped parts are formed on the ground electrodes as describe above, each of the ground electrodes may expand in area in the boundary area between the ground electrodes, and a sharp change in the boundary area may be reduced.

Although the first and second ground electrodes 31 and 32 are positioned at the same height as each other, the exemplary embodiment is not limited thereto. For example, the first and second ground electrodes 31 and 32 may have various heights. That is, the second ground electrode 32 may be positioned higher than the first ground electrode 31 and be disposed in the protrusion 21. Each of the first and second ground electrodes 31 and 32 is controlled in height to accurately control the distribution of the plasma generated on the first and second ground electrodes 31 and 32.

The first and second ground electrodes 31 and 32 are connected to the control unit 60 that is independently controlling the first and second ground electrodes 31 and 32. The control unit 60 may independently control the first and second ground electrodes 31 and 32 through one controller. Alternatively, controllers 61 and 62 are connected to the first and second ground electrodes 31 and 32, respectively and thus control the first and second ground electrodes 31 and 32 separately. The first and second ground electrodes 31 and 32 are connected to the control unit 60 through the conductive wires 33 and 34, and the control unit 60 is connected to the ground. Thus, the plurality of ground electrodes, i.e., the first and second ground electrodes 31 and 32 may be controlled to have different impedances from each other. That is, impedance applied to the first ground electrode 31 has a value different from that of the impedance applied to the second ground electrode 32. Like this, the first and second ground electrodes 31 and 32 may be controlled to have different impedances from each other to thereby control the distribution or density of the plasma generated on the first and second ground electrodes 31 and 32. Here, the control unit may include various variable components. That is, the control unit may include at least one of a variable condenser, a variable coil, and a variable resistor. Here, the impedances of the ground electrodes 31 and 32 may be controlled by varying at least one of the variable condenser, the variable coil, and the variable resistor.

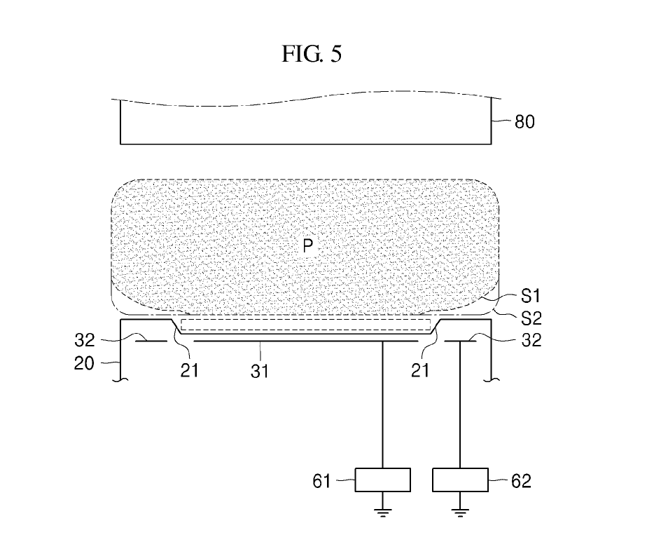

Hereinafter, a method of generating the plasma will be described below. FIG. 5 is a conceptual view illustrating a state where a plasma is generated in the substrate processing apparatus in accordance with an exemplary embodiment.

Generally, when a processing gas is excited to turn into plasma in the chamber, an ion sheath area (a plasma sheath area) including high-density positive ion species is formed at a boundary between the surface of the substrate S and the plasma because electrons are higher in drift velocity than positive ion species. Similarly, an ion sheath area is also formed at a boundary between the surface of the substrate support and the plasma. Here, since the substrate support is formed of the insulator, the ion sheath area may have a thickness greater than that of the ion sheath area on the substrate side. Thus, the ion sheath area formed on the surface of the substrate and the ion sheath area formed on the surface of the substrate support of the peripheries of the substrate may have different thicknesses. Also, plasma density is sharply changed at the edge area of the substrate due to a difference in thickness between the ion sheath area existing on the substrate and the ion sheath area existing on the surface of the substrate support. Thus, since the distribution of the plasma becomes non-uniform at the edge area of the substrate, the process, such as a thin film deposition process, is not uniformly performed on the substrate. To solve the foregoing limitation, variable parameters affecting the thin film deposition may be controlled and modified by adjusting processing steps (recipe); however, the sharp change in plasma density which occurred at the edge area of the substrate was uncontrollable.

On the other hand, in the exemplary embodiment, the plurality of ground electrodes 31 and 32 are disposed in the substrate support 20 to independently control the impedance of the edge area of the substrate support. Thus, the difference in thickness between the ion sheath area on the surface of the substrate and the ion sheath area on the surface of the substrate support may be reduced (S1-->S2) to expand the distribution area of the plasma. For example, the distribution area of the plasma is controlled by varying the impedance Z through automatic control of the variable devices to control impedance components in the chamber, that is, an inductive reactance X_{L} component and a capacitive reactance X_{c} component that are values of imagenary areas and resistance R that is a value of a real area if necessary. That is, the control unit may control the distribution (density) of the plasma on an inner portion of the substrate to be similar to the distribution (density) of the plasma on the substrate edge area and the substrate support. Since the plasma density on the substrate is almost similar to that of the periphery of the substrate, various processes in the central area and the edge area of the substrate may be uniformly performed. For example, when the thin film is deposited on the substrate, the substrate processing apparatus may allow the thin film deposited on the edge area of the substrate to have characteristic equal or similar to the thin film deposited on the central area of the substrate.

Although the apparatus in which the plasma is generated between the upper electrode and the substrate support facing each other due to the RF power is described, the exemplary embodiment is not limited thereto. For example, the exemplary embodiment may also be applied to apparatuses adopting various plasma generating methods and structures.

In accordance with the exemplary embodiment, the substrate support device and the substrate processing apparatus may uniformly control plasma distribution or density on a substrate and a periphery of the substrate and may uniformly control plasma distribution or density in the central area of the substrate and the edge area of the substrate. Also, the substrate processing apparatus may control the state of plasma on the central area of the substrate to be equal or similar to the state of the plasma on the edge area of the substrate.

Like this, the substrate processing apparatus may control the distribution and the density of the plasma to uniformly form the thickness of the thin film formed on the substrate, and the thin film deposited on the edge area of the substrate to have characteristic equal or similar to the thin film deposited on the central area of the substrate. Thus, the thin film deposited on the substrate increases in quality.

Also, in accordance with the exemplary embodiment, the substrate processing apparatus may easily control the state of the plasma generated in the chamber due to its simple structure without performing a difficult structure change or a complicated process control.

Thus, the substrate processing apparatus may efficiently perform the process for manufacturing the thin film through a simple process and increase in productivity at low cost.

Although the substrate support device and the substrate processing apparatus including the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A substrate support device supporting a substrate, the substrate support device comprising:
a substrate support on which the substrate is seated, the substrate support having a protrusion protruding from an edge area thereof;
a first ground electrode disposed in a central area of the substrate support;
a second ground electrode spaced apart from the first ground electrode and disposed in the edge area of the substrate support; and
a control unit independently controlling the first and second ground electrodes.

2. The substrate support device of claim 1, wherein the substrate support comprises an insulation material.

3. The substrate support device of claim 1, wherein the substrate support comprises a heater disposed below at least one of the first ground electrode and the second ground electrode.

4. The substrate support device of claim 1, wherein the first ground electrode has a size less than that of the substrate, and the second ground electrode has an inner diameter greater than that of the substrate.

5. The substrate support device of claim 1, wherein the first ground electrode has a first wave-shaped part on an outer circumferential surface thereof, and the second ground electrode has a second wave-shaped part on an inner circumferential surface, the second wave-shaped part corresponding to the first wave-shaped part.

6. The substrate support device of claim 5, wherein at least one portion of the first wave-shaped part protrudes outward from the substrate, and at least one portion of the second wave-shaped part protrudes inward from the substrate.

7. The substrate support device of claim 1, wherein the second ground electrode is positioned higher than the first ground electrode.

8. The substrate support device of claim 1, wherein the second ground electrode is disposed below the protrusion.

9. A substrate processing apparatus comprising:
a chamber in which a processing space is defined;
a substrate support disposed in the chamber and supporting a substrate; and
an upper electrode to which a radio frequency (RF) power is applied, the upper electrode facing the substrate support,
wherein the substrate support comprises a plurality of ground electrodes spaced apart from each other and independently controlled so that plasma is uniformly generated to an edge area of the substrate support between the upper electrode and the substrate support.

10. The substrate processing apparatus of claim 9, wherein the plurality of ground electrodes comprise a first ground electrode having a shape corresponding to that of the substrate and a second ground electrode disposed outside the first ground electrode.

11. The substrate processing apparatus of claim 10, wherein the first ground electrode has a size less than that of the substrate, and the second ground electrode disposed outside the substrate.

12. The substrate processing apparatus of claim 9, wherein the plurality of ground electrodes comprises the first ground electrode having a first curve on an outer circumferential surface thereof and the second ground electrode having a second wave-shaped part on an inner circumferential surface thereof,
wherein at least one portion of the first wave-shaped part protrudes outward from the substrate, and the second wave-shaped part is disposed outside the first ground electrode and corresponds to the first wave-shaped part.

13. The substrate processing apparatus of claim 9, comprising a control unit respectively controlling impedances of the plurality of ground electrodes.

14. The substrate processing apparatus of claim 13, wherein the control unit comprises at least one of a variable condenser, a variable coil, and a variable resistor.

15. The substrate processing apparatus of claim 13, wherein the control unit allows the plurality of ground electrodes to have different impedances.

16. The substrate processing apparatus of claim 9, wherein the substrate support comprises an insulator, and the ground electrode is formed in a film shape in the insulator.
